(19) United States
(12) Patent Application Publication
(10) Pub. No.: US 2021/0257348 A1
(43) Pub. Date: Aug. 19, 2021

(54) LIGHT EMITTING DIODE PACKAGE HAVING BACK-TO-BACK COMPARTMENT CONFIGURATION

(71) Applicants: Tek Beng LOW, Melaka (MY); Chee Sheng LIM, Melaka (MY)

(72) Inventors: Tek Beng LOW, Melaka (MY); Chee Sheng LIM, Melaka (MY)

(21) Appl. No.: 16/790,349

(22) Filed: Feb. 13, 2020

(51) Int. Cl. H01L 25/16; H01L 25/075; H01L 33/62

(52) U.S. Cl. CPC H01L 25/165; H01L 33/62; H01L 25/167; H01L 25/0753

(57) ABSTRACT

A light emitting diode package, including: a housing, wherein the housing includes a top compartment having an aperture and a bottom compartment having an aperture; a lead frame, wherein the lead frame includes a first electrode and a second electrode, and wherein the lead frame is positioned between the top compartment and the bottom compartment of the housing; at least one light emitting diode light source, wherein the at least one light emitting diode light source is associated with the aperture of the top compartment of the housing; a light emitting diode driver, wherein the light emitting diode driver is associated with the aperture of the bottom compartment of the housing; and wherein the aperture of the top compartment of the housing and the aperture of the bottom compartment of the housing are positioned in a back-to-back configuration.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A SEQUENCE LISTING

Not applicable.

### BACKGROUND OF THE INVENTION

### 1. Field of the Invention

The present invention relates in general to light emitting diode (LED) packages, and more particularly, to improved LED packages having back-to-back compartment/window configurations that provide for substantially enhanced performance characteristics.

### 2. Background Art

LED packages have been known in the art for years and are the subject of a plurality of patents and publications, including: U.S. Pat. No. 9,559,275 entitled “Light Emitting Device Package and Light Unit Having the Same,” U.S. Pat. No. 8,394,675 entitled “Manufacturing Light Emitting Diode (LED) Packages,” U.S. Pat. No. 8,314,479 entitled “Leadframe Package with Recessed Cavity for LED,” U.S. Pat. No. 7,646,029 entitled “LED Package Methods and Systems,” U.S. Pat. No. 6,407,411 entitled “LED Lead Frame Assembly,” U.S. Patent Application Publication No. 2005/0179041 entitled “Illumination System with LEDs,” U.S. Patent Application Publication No. 2003/0116769 entitled “Light Emission Diode Package,” U.S. Patent Application Publication No. 2002/0180345 entitled “Package Structure Containing Two LEDs,” International Application Publication No. WO 2009/082177 entitled “Light Emitting Diode Package,” and International Application Publication No. WO 2009/072786 entitled “LED Package and Method for Fabricating the Same”—all of which are hereby incorporated herein by reference in their entirety including all references cited therein.

U.S. Pat. No. 9,559,275 appears to disclose a light emitting device package. The light emitting device is a package body that includes a first recess which is provided with a bottom face and a plurality of inner walls surrounding the bottom face, the plurality of inner walls including a first inner wall and a second inner wall, which are opposing walls; a lead frame exposed at the bottom face of the package body, the lead frame including a bottom frame and a reflector exposed along one of the first inner wall and the second inner wall; a light emitting element provided on the lead frame; and a transparent material provided in the package body to cover the light emitting element. A material of the reflector is the same as a material of the bottom frame of the lead frame.

U.S. Pat. No. 8,394,675 appears to disclose a method of manufacturing an LED package that includes mounting a large panel frame/substrate (LPF/S) having a substantially square shape to a ring. The LPF/S includes a plurality of die pads and a corresponding plurality of leads arranged in a matrix pattern. Each of the die pads includes a planar chip attach surface. An LED chip is attached to the planar chip attach surface of each of the die pads. An encapsulant material is applied overlaying the LED chips and at least a part of the LPF/S. Each die pad and corresponding leads are separated from the LPF/S to form individual LED packages. The steps of attaching the LED chips and applying the encapsulant material are performed while the LPF/S is mounted to the ring.

U.S. Pat. No. 8,314,479 appears to disclose an LED package that includes a die pad having a bottom surface, an upper surface and a centrally located recessed cavity. The recessed cavity has a chip attach surface between the bottom surface and upper surface and sidewalls that extend from the recessed chip attach surface to the upper surface. The package additionally has leads arranged on opposing sides of the die pad. The leads have a bottom surface that is coextensive with the bottom surface of the die pad and an upper surface coextensive with the upper surface of the die pad. An LED chip is attached to the chip attach surface. The package further includes a package body having an encapsulant which fills space between the die pad and leads forming a bottom encapsulant surface that is coextensive with the bottom surfaces of the die pad and leads.

U.S. Pat. No. 7,646,029 appears to disclose methods and systems for LED modules that include an LED die integrated in an LED package with a submount that includes an electronic component for controlling the light emitted by the LED die. The electronic component integrated in the submount may include drive hardware, a network interface, memory, a processor, a switch-mode power supply, a power facility, or another type of electronic component.

U.S. Pat. No. 6,407,411 appears to disclose an improved LED lead frame packaging assembly that includes a thermally conducting, electrically insulating material that enhances the thermal conduction and structural integrity of the assembly, a UV-resistant encapsulant material, and an integral ESD material that reduces electrostatic discharge. The thermally conducting, electrically insulating material creates an electrically insulating, thermally conductive path in the lead frame assembly for dissipation of power and also acts as a mounting structure thus allowing for the use of a soft encapsulant material, preferably a silicone.

U.S. Patent Application Publication No. 2005/0179041 appears to disclose a system that includes a light emitting diode (LED), such as a projection system, which may be increased by using an LED chip that has a light emitting surface that emits light directly into any medium with a refractive index of less than or equal to approximately 1.25. For example, the LED chip may emit light directly into the ambient environment, such as air or gas, instead of into an encapsulant. The low refractive index decreases the étendue of the LED, which increases luminance. Moreover, without an encapsulant, a collimating optical element, such as a lens, can be positioned close to the light emitting surface of the LED chip, which advantageously permits the capture of light emitted at large angles. A secondary collimating optical element may be used to assist in focusing the light on a target, such as a micro-display.

U.S. Patent Application Publication No. 2003/0116769 appears to disclose an LED package, made of ceramic substrates and having a reflective metal plate. This LED package consists of a first ceramic substrate, which has a chip mounting area on its top surface, and is provided with a predetermined conductive pattern formed around the chip mounting area. One or more LED chips are seated on the chip mounting area of the first ceramic substrate, and are connected to the conductive pattern. A second ceramic substrate is mounted on the top surface of the first ceramic substrate and has a cavity at a position corresponding to the chip mounting area. The reflective metal plate is set in the cavity of the second ceramic substrate to surround the LED chips. This LED package effectively controls the luminous intensity of the LED chips and the angular distribution of the luminance. The reflective metal plate also collaterally acts as a heat sink effectively dissipating heat from the LED chips to the surroundings of the LED package.

U.S. Patent Application Publication No. 2002/0180345 appears to disclose a package structure containing two LEDs (light emitting diodes), which are packaged in cascade and capable of emitting lights with different wavelengths. For example, by packaging a yellow LED die above a blue LED die or packaging a blue LED die above a yellow LED die, a desaturated blue, desaturated yellow or white light can be obtained when a blue light is emitted through a yellow light or a yellow light is emitted through a blue light. The present invention can be a single-anode-single-cathode or a double-anode-single-cathode package structure, wherein the latter structure can continually change the emitted light in a certain range by adjusting input voltages of the anodes.

International Application Publication No. WO 2009/082177 appears to disclose a light emitting diode (LED) package that includes a light emitting diode (LED) package that includes a pair of lead frames connected with at least one LED chip through a metal wire, a package body integrally fixed with the lead frames and having a cavity having an open top, a lead frame bent downwardly to a lower part of an external mounting surface of the package body, a light-transmissive, transparent resin covering the LED chip and filling the cavity, a recess formed in a bottom surface of the cavity, in which the LED chip is mounted, and a transparent resin including a fluorescent material formed in the recess and the cavity. Accordingly, the amount of light-transmissive, transparent resin filling the cavity is reduced to save on manufacturing costs, and the height of the resin is lowered to improve the luminance of light. Also, the height of the package body is lowered, contributing to manufacturing a small product.

International Application Publication No. WO 2009/072786 appears to disclose an LED package that comprises a base having an LED chip mounted thereon, an encapsulation member formed by a light-transmittable resin to encapsulate the LED chip, and a housing formed to expose a top portion of the encapsulation member and to encompass a side surface of the encapsulation member, wherein the encapsulation member is formed by a transfer molding process using a mold to have a predetermined shape. Further, the housing may be light-transmittable.

While the above-identified patents do appear to disclose a plurality of LED package configurations, none of the above-identified patents appear to disclose an LED package having a back-to-back compartment/window configuration that provides for substantially enhanced performance characteristics.

These and other objects of the present invention will become apparent in light of the present specification, claims, and drawings.

### SUMMARY OF THE INVENTION

The present invention is directed to a light emitting diode package, comprising, consisting essentially of, and/or consisting of: (a) a housing, wherein the housing comprises a top compartment having an aperture and a bottom compartment having an aperture; (b) a lead frame, wherein the lead frame comprises a first electrode and a second electrode, and wherein the lead frame is positioned between the top compartment and the bottom compartment of the housing; (c) one or more light emitting diode light sources, wherein the one or more light emitting diode light sources are associated with the aperture of the top compartment of the housing; (d) a light emitting diode driver, wherein the light emitting diode driver is associated with the aperture of the bottom compartment of the housing; and (e) wherein the aperture of the top compartment of the housing and the aperture of the bottom compartment of the housing are positioned in a back-to-back configuration.

In a preferred embodiment of the present invention, the top compartment of the housing is positioned above a top surface of the lead frame.

In another preferred embodiment of the present invention, the bottom compartment of the housing is positioned below a bottom surface of the lead frame.

In yet another preferred embodiment of the present invention, the first electrode comprises an anode, and the second electrode comprises a cathode.

In one embodiment of the present invention, the first electrode comprises a pair of anodes, and the second electrode comprises a pair of cathodes.

In a preferred embodiment of the present invention, the area of the first electrode and the area of the second electrode are not equal.

In another preferred embodiment of the present invention, the one or more light emitting diode light sources comprise three light emitting diode light sources. In this embodiment, the three light emitting diode light sources comprise the same or different color and/or intensity.

In yet another preferred embodiment of the present invention, the one or more light emitting diode light sources comprise a red, green, and blue (RGB) light emitting diode light source.

In one aspect of the present invention, the light emitting diode light source and the light emitting diode driver are in bi-lateral electrical communication.

In a preferred embodiment of the present invention, the light emitting diode driver comprises the ability to allow LEDs to be triggered and locked with a designated brightness and/or color. The driver also enables current tuning with response to ambient temperature.

The present invention is also directed to a light emitting diode package, comprising, consisting essentially of, and/or consisting of: (a) a housing, wherein the housing comprises a top compartment having an aperture and a bottom compartment having an aperture; (b) a lead frame, wherein the lead frame comprises a first electrode and a second electrode, and wherein the lead frame is positioned between the top compartment and the bottom compartment of the housing; (c) three light emitting diode light sources, wherein the three light emitting diode light sources are associated with the aperture of the top compartment of the housing; (d) a light emitting diode driver, wherein the light emitting diode driver is associated with the aperture of the bottom compartment of the housing; (e) wherein the aperture of the top compartment of the housing and the aperture of the bottom compartment of the housing are positioned in a back-to-back configuration; (f) wherein the three light emitting diode light sources comprise the same or different colors and/or intensities; and (g) wherein the three light emitting diode light sources and the light emitting diode driver are in bi-lateral electrical communication.

The present invention is further directed to a light emitting diode package, comprising, consisting essentially of, and/or consisting of: (a) a housing, wherein the housing comprises a top compartment having an aperture and a bottom compartment having an aperture; (b) a lead frame, wherein the lead frame comprises a first electrode and a second electrode, and wherein the lead frame is positioned between the top compartment and the bottom compartment of the housing; (c) at least one light emitting diode light source, wherein the at least one light emitting diode light source is associated with the aperture of the top compartment of the housing; (d) a light emitting diode driver, wherein the light emitting diode driver is associated with the aperture of the bottom compartment of the housing; (e) wherein the aperture of the top compartment of the housing and the aperture of the bottom compartment of the housing are positioned in a back-to-back configuration; (f) wherein the top compartment of the housing is positioned above a top surface of the lead frame; (g) wherein the bottom compartment of the housing is positioned below a bottom surface of the lead frame; (h) wherein the first electrode comprises an anode; (i) wherein the second electrode comprises a cathode; and (j) wherein the at least one light emitting diode light source and the light emitting diode driver are in bi-lateral electrical communication.

### BRIEF DESCRIPTION OF THE DRAWINGS

Certain embodiments of the present invention are illustrated by the accompanying figures. It will be understood that the figures are not necessarily to scale and that details not necessary for an understanding of the invention or that render other details difficult to perceive may be omitted.

It will be further understood that the invention is not necessarily limited to the particular embodiments illustrated herein.

The invention will now be described with reference to the drawings wherein:

FIG. 1 is a front perspective view of a light emitting diode package of the present invention;

FIG. 2 is a top view of the light emitting diode package of FIG. 1;

FIG. 3 is a bottom view of the light emitting diode package of FIG. 1;

FIG. 4 is a front view of the light emitting diode package of FIG. 1;

FIG. 5 is a rear view of the light emitting diode package of FIG. 1;

FIG. 6 is a left side view of the light emitting diode package of FIG. 1;

FIG. 7 is a right side view of the light emitting diode package of FIG. 1;

FIG. 8 is an enlarged top view of a light emitting diode package of the present invention;

FIG. 9 is an enlarged side view of the light emitting diode package of FIG. 8;

FIG. 10 is an enlarged bottom view of the light emitting diode package of FIG. 8;

FIG. 11 is an enlarged side view of the light emitting diode package of FIG. 8; and

FIG. 12 is an enlarged view of the back-to-back light emitting diode package illustrating one or more common leads and one or more dummy leads in accordance with one or more embodiments of the present invention.

### DETAILED DESCRIPTION OF THE INVENTION

While this invention is susceptible of embodiment in many different forms, there is shown in the drawings and described herein in detail several specific embodiments with the understanding that the present disclosure is to be considered as an exemplification of the principles of the invention and is not intended to limit the invention to the embodiments illustrated.

It will be understood that like or analogous elements and/or components, referred to herein, may be identified throughout the drawings by like reference characters. In addition, it will be understood that the drawings are merely schematic representations of one or more embodiments of the invention, and some of the components may have been distorted from their actual scale for purposes of pictorial clarity.

Various embodiments of the present invention relate to LED packages having back-to-back compartment/window configurations that provide for substantially enhanced performance characteristics.

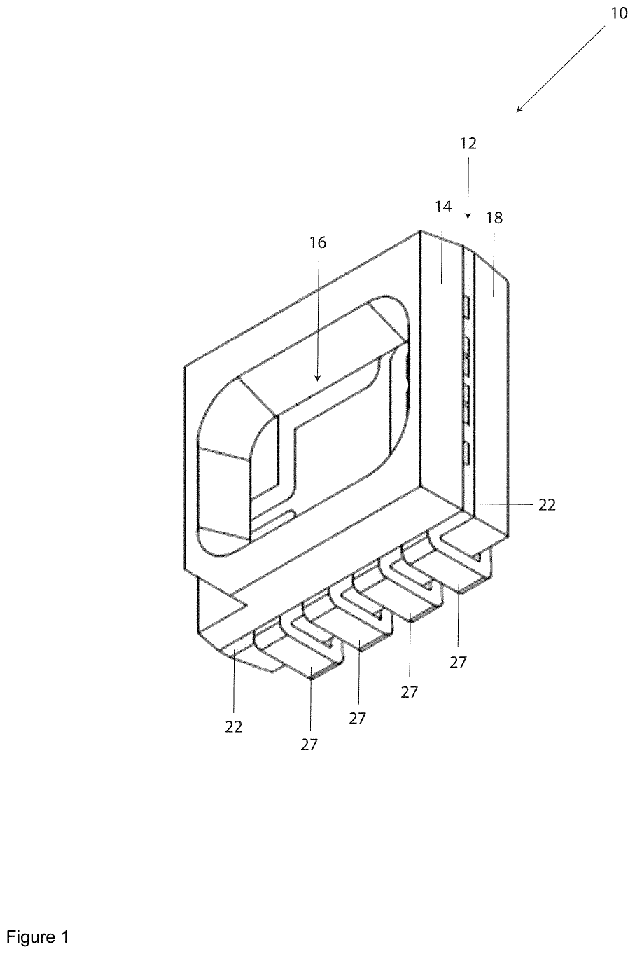

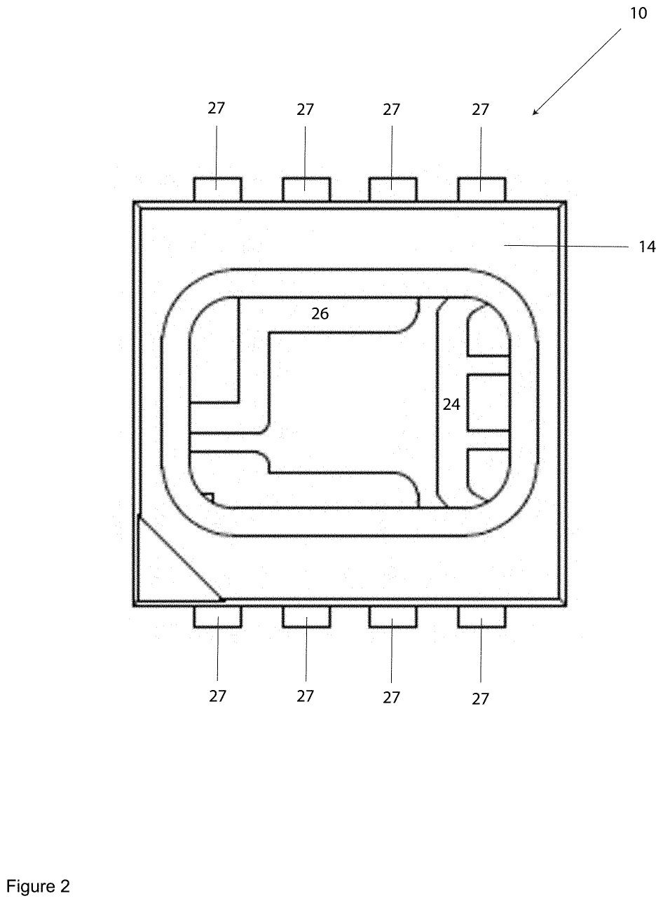

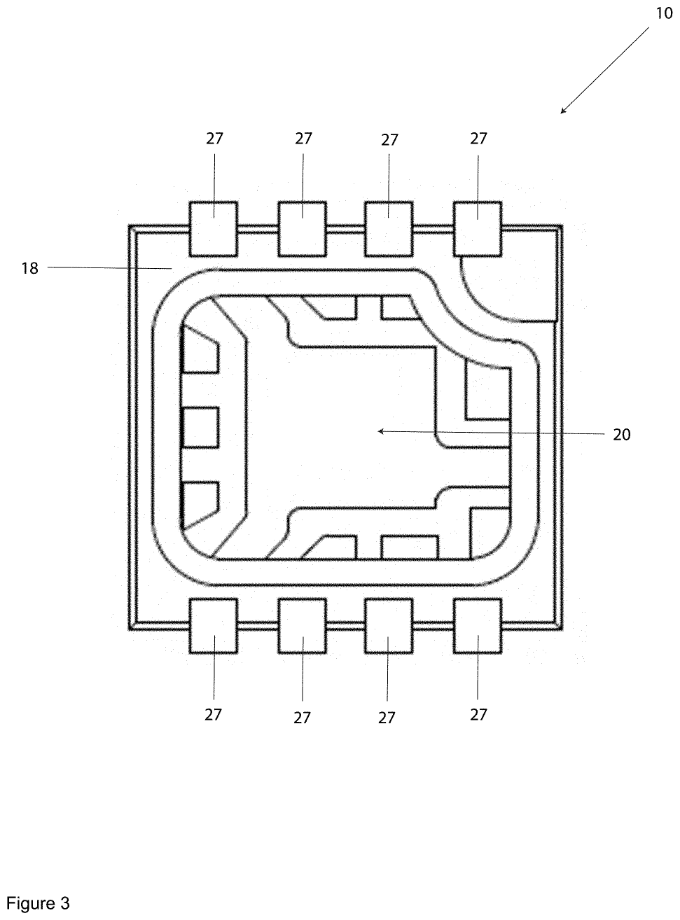

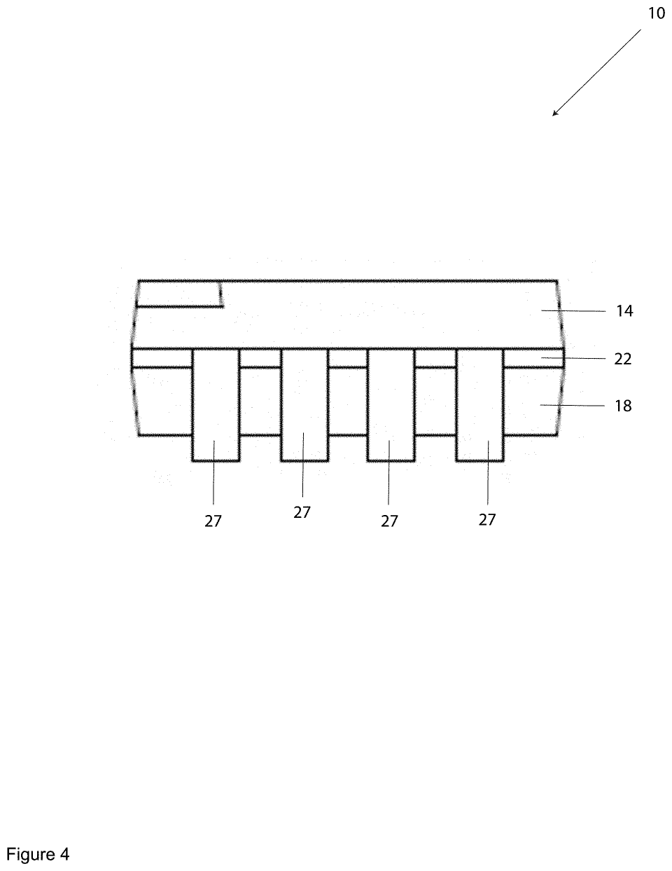

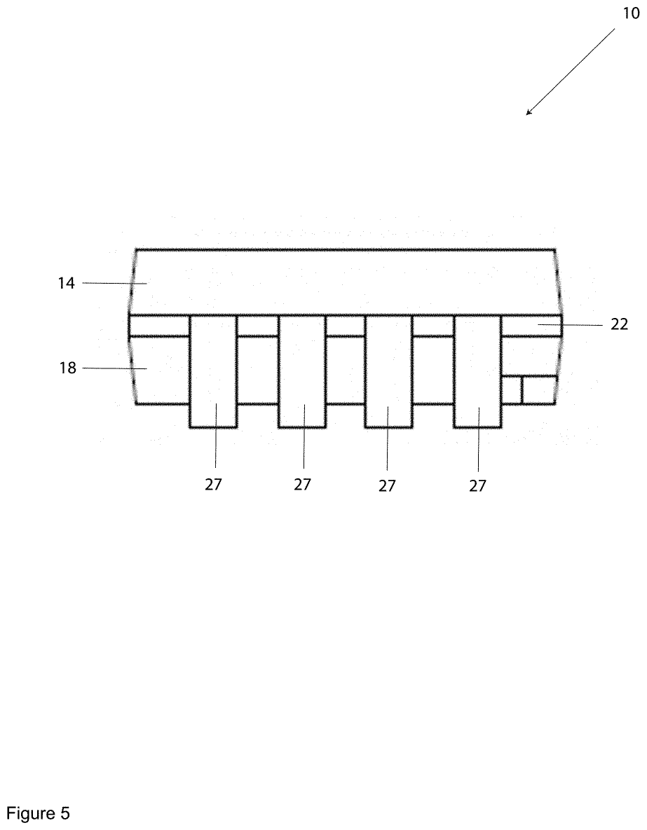

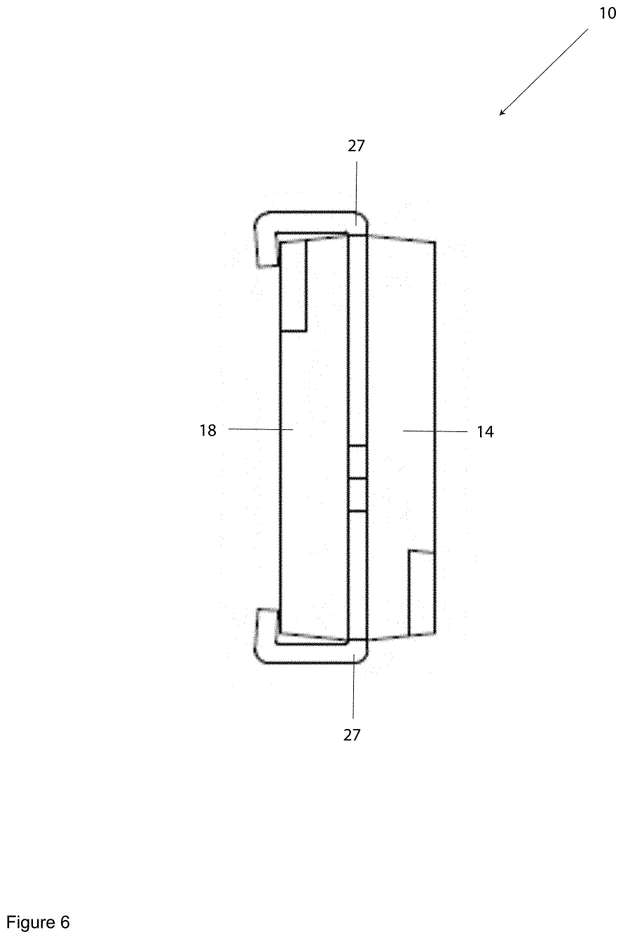

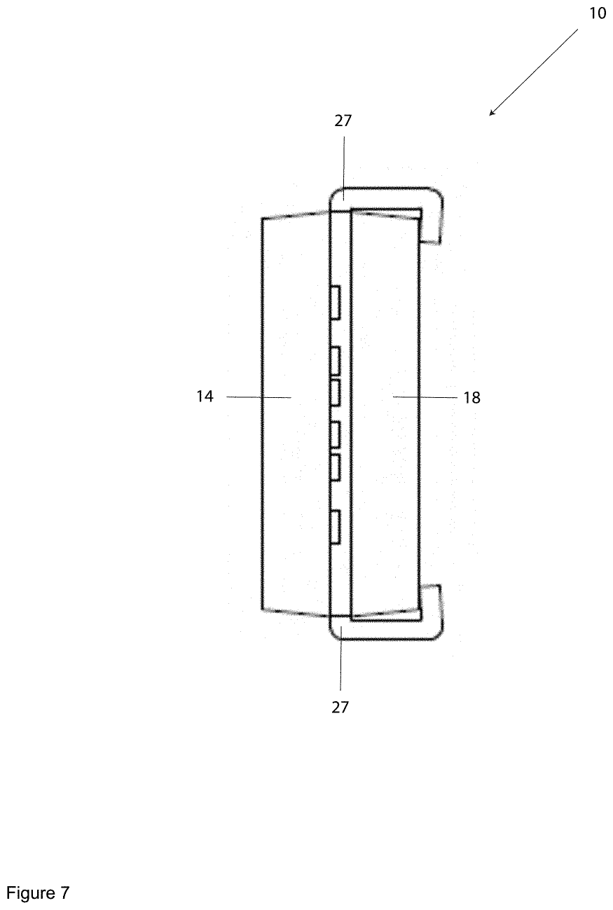

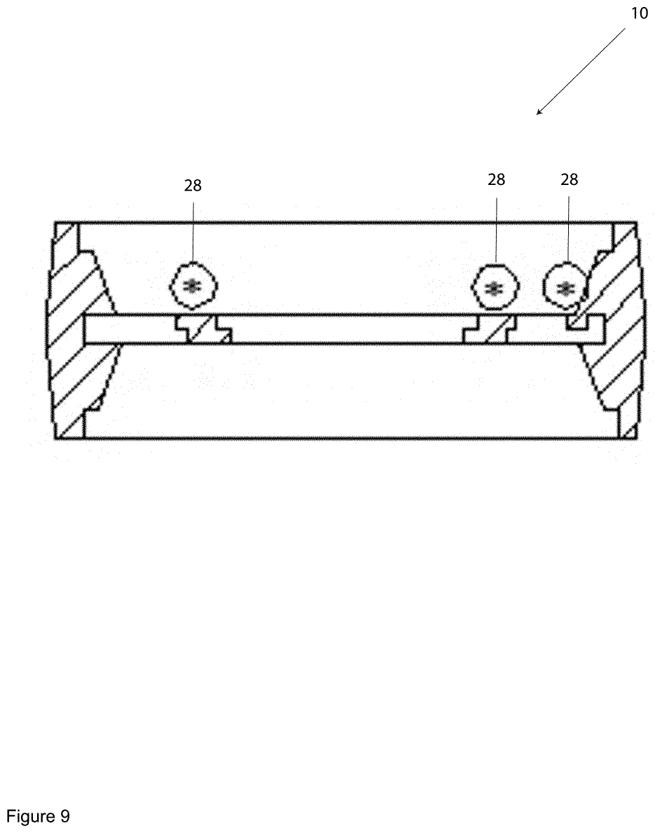

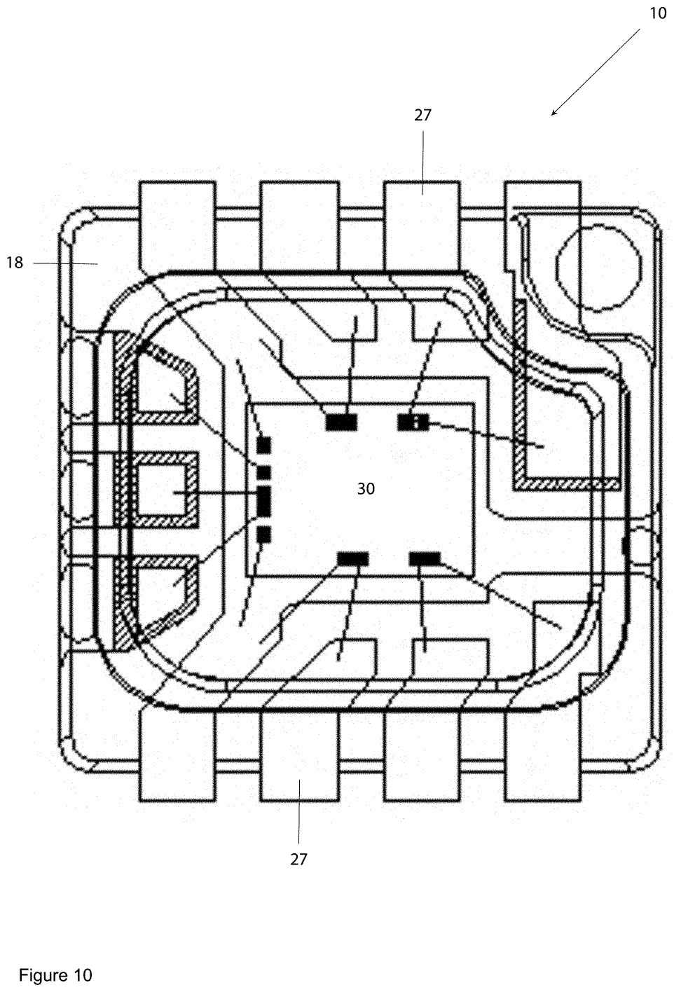

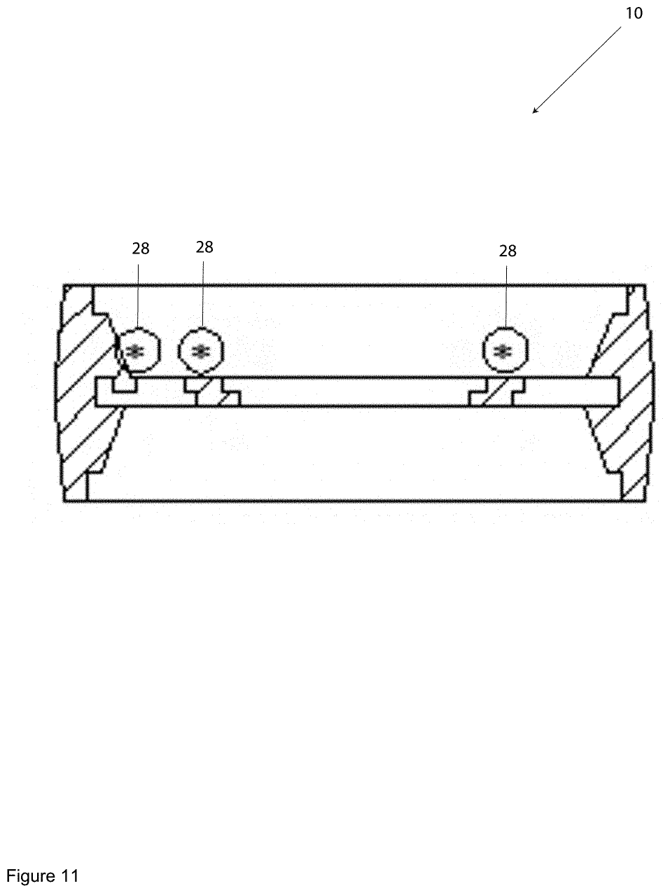

Referring now to FIGS. 1-12, light emitting diode package 10 is shown as including: housing 12 comprising top compartment 14 having aperture 16, and bottom compartment 18 having aperture 20; lead frame 22, wherein lead frame 22 comprises first electrode 24 (e.g., anode) and second electrode 26 (e.g., cathode) and associated leads 27, and wherein lead frame 22 is positioned between top compartment 14 and the bottom compartment 18 of the housing 12; one or more one light emitting diode light sources 28, wherein the one or more light emitting diode light source 28 are associated with aperture 16 of top compartment 14 of housing 12; light emitting diode driver 30, wherein light emitting diode driver 30 is associated with aperture 20 of bottom compartment 18 of housing 12; and wherein aperture 16 of top compartment 14 of housing 12 and aperture 20 of bottom compartment 18 of housing 12 are positioned in a back-to-back configuration.

Referring now to FIG. 1, top compartment 14 of housing 12 is positioned above a top surface of lead frame 22, and bottom compartment 18 of housing 12 is positioned below a bottom surface of lead frame 22.

In one embodiment of the present invention, the first electrode preferably comprises a pair of anodes, and the second electrode preferably comprises a pair of cathodes. In this embodiment, the area of the first electrode and the area of the second electrode are the same or different.

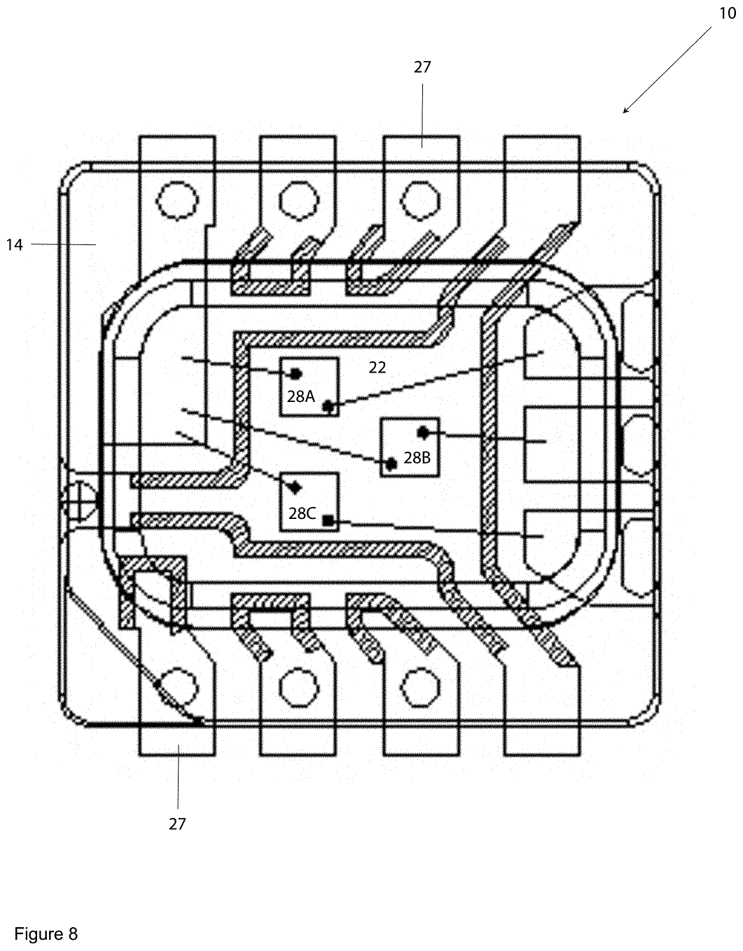

As is best shown in FIGS. 8-11, the light emitting diode light source optionally comprises three light emitting diode light sources 28A-28C. In this embodiment, the three light emitting diode light sources optionally comprise the same color and/or intensity. In another embodiment of the present invention, the three light emitting diode light sources comprises an RGB LED's.

In accordance with the present invention, one or more light emitting diode light sources 28 and light emitting diode driver 30 are preferably in bi-lateral electrical communication.

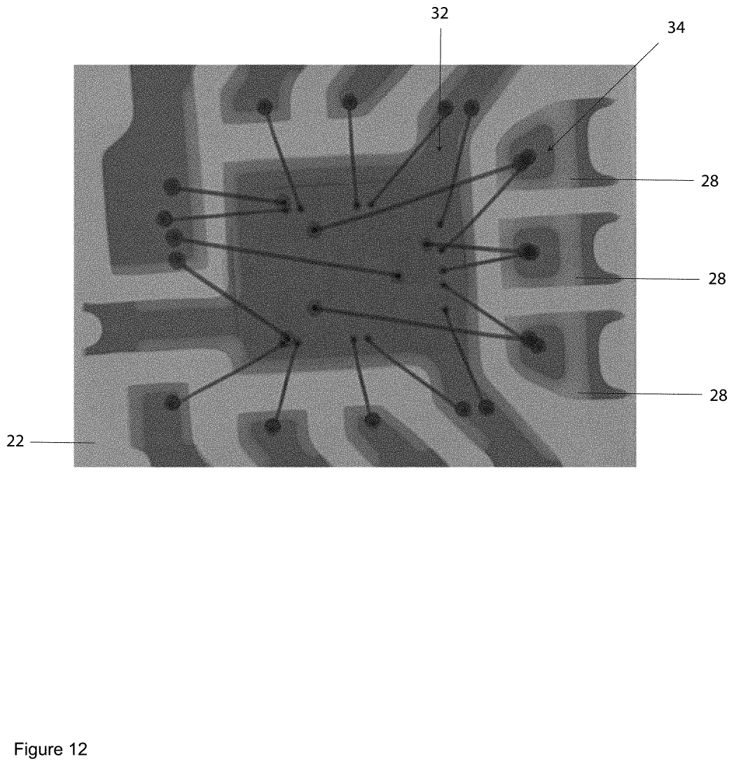

Referring now to FIG. 12, light emitting diode driver 30 preferably comprises components that enable LEDs to be triggered and locked with a designated brightness and/or color. The driver also enables current tuning with response to ambient temperature. It will be understood that one or more common leads 32 and dummy leads 34 are cooperatively utilized to place the integrated circuit (e.g., light emitting diode driver 30) and one or more LED's 28 in a back-to-back configuration.

The foregoing description merely explains and illustrates the invention and the invention is not limited thereto except insofar as the appended claims are so limited, as those skilled in the art who have the disclosure before them will be able to make modifications without departing from the scope of the invention.

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etcetera shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etcetera. As a non-limiting example, each range discussed herein can be readily broken down into a lower third, middle third and upper third, etcetera. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Other embodiments are set forth in the following claims.

1. A light emitting diode package, comprising:
a housing, wherein the housing comprises a top compartment having an aperture and a bottom compartment having an aperture;
a lead frame, wherein the lead frame comprises a first electrode and a second electrode, and wherein the lead frame is positioned between the top compartment and the bottom compartment of the housing;
at least one light emitting diode light source, wherein the at least one light emitting diode light source is associated with the aperture of the top compartment of the housing;
a light emitting diode driver, wherein the light emitting diode driver is associated with the aperture of the bottom compartment of the housing;
wherein the aperture of the top compartment of the housing and the aperture of the bottom compartment of the housing are positioned in a back-to-back configuration; and
wherein the at least one light emitting diode light source and the light emitting diode driver are in bi-lateral electrical communication.

2. The light emitting diode package according to claim 1, wherein the top compartment of the housing is positioned above a top surface of the lead frame.

3. The light emitting diode package according to claim 1, wherein the bottom compartment of the housing is positioned below a bottom surface of the lead frame.

4. The light emitting diode package according to claim 1, wherein the first electrode comprises an anode.

5. The light emitting diode package according to claim 1, wherein the second electrode comprises a cathode.

6. The light emitting diode package according to claim 1, wherein the first electrode comprises a pair of anodes.

7. The light emitting diode package according to claim 1, wherein the second electrode comprises a pair of cathodes.

8. The light emitting diode package according to claim 1, wherein the area of the first electrode and the area of the second electrode are not equal.

9. The light emitting diode package according to claim 1, wherein the at least one light emitting diode light source comprises three light emitting diode light sources.

10. The light emitting diode package according to claim 9, wherein the three light emitting diode light sources comprise the same color and/or intensity.

11. The light emitting diode package according to claim 1, wherein the at least one light emitting diode light source comprises an RGB light emitting diode light source.

12. (canceled)

13. The light emitting diode package according to claim 1, wherein the light emitting diode driver comprises the ability to allow LEDs to be triggered and locked with a designated brightness and/or color and/or enables current tuning with response to ambient temperature.

14. A light emitting diode package, comprising:
a housing, wherein the housing comprises a top compartment having an aperture and a bottom compartment having an aperture;
a lead frame, wherein the lead frame comprises a first electrode and a second electrode, and wherein the lead frame is positioned between the top compartment and the bottom compartment of the housing;
three light emitting diode light sources, wherein the three light emitting diode light sources are associated with the aperture of the top compartment of the housing;
a light emitting diode driver, wherein the light emitting diode driver is associated with the aperture of the bottom compartment of the housing;
wherein the aperture of the top compartment of the housing and the aperture of the bottom compartment of the housing are positioned in a back-to-back configuration;
wherein the three light emitting diode light sources comprise the same or different colors and/or intensities; and
wherein the three light emitting diode light sources and the light emitting diode driver are in bi-lateral electrical communication.

15. A light emitting diode package, comprising:
a housing, wherein the housing comprises a top compartment having an aperture and a bottom compartment having an aperture;
a lead frame, wherein the lead frame comprises a first electrode and a second electrode, and wherein the lead frame is positioned between the top compartment and the bottom compartment of the housing;
at least one light emitting diode light source, wherein the at least one light emitting diode light source is associated with the aperture of the top compartment of the housing;
a light emitting diode driver, wherein the light emitting diode driver is associated with the aperture of the bottom compartment of the housing;
wherein the aperture of the top compartment of the housing and the aperture of the bottom compartment of the housing are positioned in a back-to-back configuration;
wherein the top compartment of the housing is positioned above a top surface of the lead frame;
wherein the bottom compartment of the housing is positioned below a bottom surface of the lead frame;
wherein the first electrode comprises an anode;
wherein the second electrode comprises a cathode; and
wherein the at least one light emitting diode light source and the light emitting diode driver are in bi-lateral electrical communication.
